(19) United States
(12) Patent Application Publication
(10) Pub. No.: US 2003/0209750 A1
(43) Pub. Date: Nov. 13, 2003

(54) Semiconductor layer with laterally variable doping, and method for producing it

(75) Inventors: Gerald Deboy, Unterhaching (DE); Wolfgang Werner, Munchen (DE)

Correspondence Address: LAURENCE A. GREENBERG, P.O. Box 2480, Hollywood, FL, 33022, US

(73) Assignee: Infineon Technologies AG

(21) Appl. No.: 10/452,479

(22) Filed: Jun. 2, 2003

Related U.S. Application Data
(62) Division of application No. 09/356,815, filed on Jul. 19, 1999, now abandoned.
(60) Provisional application No. 60/093,245, filed on Jul. 17, 1998.

(51) Int. Cl. H01L 27/108

(52) U.S. Cl. 257/301

(57) ABSTRACT

A semiconductor layer with laterally variable doping, and a method for producing it are disclosed. The trenches here are no longer filled up completely with doped semiconductor material. Instead, a doped balancing layer is deposited in a sense as a lining on the walls of the trenches. The doped balancing layer has a defined layer thickness that remains constant over an entire depth of the trenches. Furthermore, both a dopant concentration and the layer thickness of the balancing layer are adjusted such that a complete charge required for compensation is already contained in the balancing layer. The trenches here can advantageously have an arbitrarily great berm angle. The invention is especially advantageous in a peripheral region of semiconductor components with high depletion voltage strength.

### CROSS-REFERENCE TO RELATED APPLICATION

This is a divisional of U.S. application Ser. No. 09/356,815, filed Jul. 19, 1999, which claimed the benefit under 35 U.S.C. §119(c) of provisional application No. 60/093,245, filed Jul. 17, 1998.

### BACKGROUND OF THE INVENTION

### Field of the Invention

The present invention relates to a semiconductor layer with laterally variable doping and to a method for producing it. The semiconductor layer has at least one trench formed therein and at least one doped layer disposed on the trench walls for charge carrier compensation. The laterally variable doping may for instance involve a laterally variable dopant concentration or a laterally variable dopant type.

The present invention relates in particular to dopant-structured semiconductor layers of semiconductor components, in which the doping of the semiconductor layers is created by etching trenches and filling the trenches with doped semiconductor material. Particularly in high-voltage semiconductor components with high depletion voltage strength, such as MOSFETs and IGBTs, so-called paired balancing zones and balancing zones complementary to them can be produced by lateral structuring of the track regions. The balancing zones and the complementary balancing zones typically have a precisely adjustable dopant concentration.

Since, because of their high doping the balancing zones and the complementary balancing zones have very good conductivity, it can be assured that in the depletion mode of the semiconductor component, the balancing zones and the complementary balancing zones balance one another out, and as a result a high depletion voltage is preserved. Since moreover a total quantity of dopant in the balancing zones is approximately equal to a total quantity of dopant in the complementary balancing zones, it is assured that if the depletion voltages rise, the pn junctions thus formed between the balancing zones and the complementary balancing zones will balance one another out completely. That is, ideally they will behave like an insulator zone, and as a result a very high depletion voltage remains assured.

The precise function as well as the structure and production of such balancing zones and complementary balancing zones is described in detail in International Patent Application WO 97/29508 and U.S. Pat. No. 4,754,310 and are hereby expressly incorporated by reference into the subject of the present application.

Lateral structuring of semiconductor layers with laterally different doping in the active zone of the semiconductor components, with the goal of drastically reducing the resistance per unit of surface area, requires for its production a very complicated technology for etching and filling deep trenches. One major demand made of this so-called trench technology is the production of trench walls that range from vertical to slightly inclined.

However, as the depth increases and at a high lateral etching rate, the trench walls assume an increasingly curved form.

Even in very exact, anisotropic trench etching processes, the trenches typically have a slight taper toward the depth of the semiconductor body. Even at a relatively slight berm angle of these trenches of say 89°, a trench 2 μm wide is already narrowed by 1 μm at a depth of 40 μm. The trench is undesirably then completely filled, and the consequence of the tapering is a charge density per unit of surface area that decreases quadratically (for round trenches) or linearly (for striplike trenches) as a function of the depth. However, then an exact charge compensation is no longer assured, and thus the depletion voltage behavior of the semiconductor component undesirably also drops as a function of the depth.

In practice until now, because of the not insignificant berm angle, it has been impossible to achieve a satisfactory semiconductor layer with laterally variable doping, in which the laterally different dopings have the same charge density per unit of surface area over the entire depth of the trenches.

### SUMMARY OF THE INVENTION

It is accordingly an object of the invention to provide a semiconductor layer with laterally variable doping which overcome the above-mentioned disadvantages of the prior art methods and devices of this general type, in which the laterally different dopings have the same charge density per unit of surface area over the entire depth of the trenches.

With the foregoing and other objects in view there is provided, in accordance with the invention, a semiconductor body with laterally variable doping, including a semiconductor layer having a surface and at least one trench formed therein extending from the surface into the semiconductor layer to a given depth and having trench walls; and at least one doped layer disposed in the at least one trench and connected to the trench walls for charge carrier compensation, the at least one doped layer having a layer thickness remaining substantially constant over an entire area of the given depth of the at least one trench, and twice the layer thickness of the at least one doped layer being less than a minimum spacing of the trench walls from one another.

The particular advantage of the invention is that the trench walls need no longer to be disposed as vertically as possible in order to achieve an optimal, constant charge density per unit of surface area over the entire depth of the trenches. Instead, the trenches may have an arbitrarily major berm angle. The trenches are no longer completely filled with doped semiconductor material here. Instead, a doped balancing layer is deposited in a sense as a lining on the walls of the trenches. The balancing layer has a defined layer thickness that remains constant over the entire depth of the trenches.

Furthermore, both the dopant concentration and the layer thickness of the balancing layer are adjusted such that the complete charge required for compensation is already contained in the balancing layer.

As a result, tapering in round trenches merely leads to a virtually linear decrease in the charge per unit of surface area as a function of the depth, and in strip shaped trenches it even leads to a constant charge per unit of surface area. The prerequisite for this is merely that the layer thickness of the balancing layer be selected as so slight that the trench has not yet grown shut anywhere.

In a highly advantageous refinement, particularly in round trenches, the charge per unit of surface area that decreases linearly with increasing depth can be compensated for by the fact that the layer thickness of the remaining layers increases as a function of the depth to the extent to which the charge density per unit of surface area decreases as a consequence of the berm angle of the trench walls. This layer thickness that increases as a function of the depth can advantageously be accomplished by imposing a temperature gradient, adding etching gases during deposition, or incorporating suitable back etching steps. In particular, the relative decrease in charge per unit of surface area for round trenches can also be varied via the starting diameter of the respective trenches and thus via a configuration dimension.

In the case discussed above, the semiconductor layer in which the trenches have been etched is doped and thus forms the track region of the semiconductor body. The balancing layers have been incorporated into the track region surrounding them, for the sake of compensating for the charge per unit of surface area. However, it would also be conceivable for the semiconductor layer to be undoped or doped only very weakly. In that case, it is especially advantageous if two adjoining zones in the trenches each have opposite conductivity types. One zone represents the track region, and the other zone is the balancing layer for charge compensation in the track region in the depletion mode. The charge density per unit of surface area required for charge compensation in both zones can be adjusted very exactly in both zones—even if the trenches are angled very sharply—by way of both their layer thicknesses and their dopant doses.

The trenches according to the invention can also especially advantageously be used to generate peripheral structures or peripheral terminations of semiconductor components. The doping per unit of surface area of the track region should increase incrementally in the direction of the peripheral region of the semiconductor component, in the sense of an optimal configuration of the course of field intensity. By way of a trench diameter that decreases radially outward in the peripheral region, the charge compensation of the basic doping in the semiconductor layer can be reduced in such a way that even a net doping that increases toward the outside results. In principle, reducing the depth of the trenches or a charge per unit of surface area inside the trenches toward the periphery that decreases as a function of the depth can lead to the same result.

Other features which are considered as characteristic for the invention are set forth in the appended claims.

Although the invention is illustrated and described herein as embodied in a semiconductor layer with laterally variable doping, and method for producing it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 a fragmentary, perspective, sectional view of a semiconductor layer with a strip shaped trench, which has a balancing layer disposed on a trench wall according to the invention;

FIG. 2 is a fragmentary, perspective, sectional view of a further exemplary embodiment of the semiconductor layer with the balancing layer in which the trench is round; and

FIG. 3 is a fragmentary, perspective, sectional view of a further exemplary embodiment of the semiconductor layer, in which the strip shaped trench has a first balancing layer and a second complementary balancing layer.

### DESCRIPTION OF THE PREFERRED EMBODIMENTS

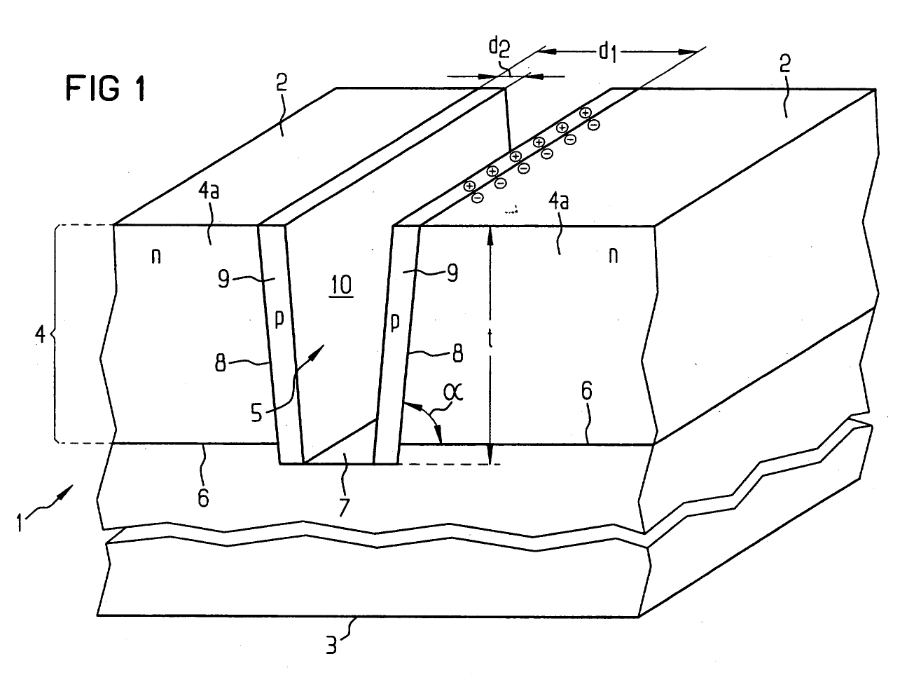

In all the figures of the drawing, sub-features and integral parts that correspond to one another bear the same reference symbol in each case. Referring now to the figures of the drawing in detail and first, particularly, to FIG. 1 thereof, there is shown a fragmentary perspective view of a section through a semiconductor layer with a strip shaped trench, which has a balancing layer according to the invention disposed on a trench wall.

In FIG. 1, reference numeral 1 indicates a semiconductor body. The semiconductor body 1 has a first surface 2 and a second surface 3. Typically, the semiconductor body 1 is highly doped, but its conductivity type or dopant concentration is of no further significance for the remainder of the invention. Between the first surface 2 and a boundary face 6 in the semiconductor body 1, a semiconductor layer 4 is disposed in the semiconductor body 1. In the present exemplary embodiment, the semiconductor layer 4 forms an n-doped track region 4a of a semiconductor component. The boundary face 6 may be embodied as a pn junction between the semiconductor layer 4 and a bulk region of the semiconductor body 1.

Also provided in the semiconductor layer 4 are a plurality of trenches 5, only one of which is shown in FIG. 1 for the sake of simplicity. The trench 5 extends from the first surface 2 of the semiconductor layer 4 through the semiconductor layer 4 into the semiconductor body 1 to a depth t. Naturally it would also be conceivable for the trench 5 to be disposed merely within the semiconductor layer 4. In principle, it is also conceivable for the trenches 5 to extend from the top first surface 2 through to the back second surface 3 of the semiconductor body 1.

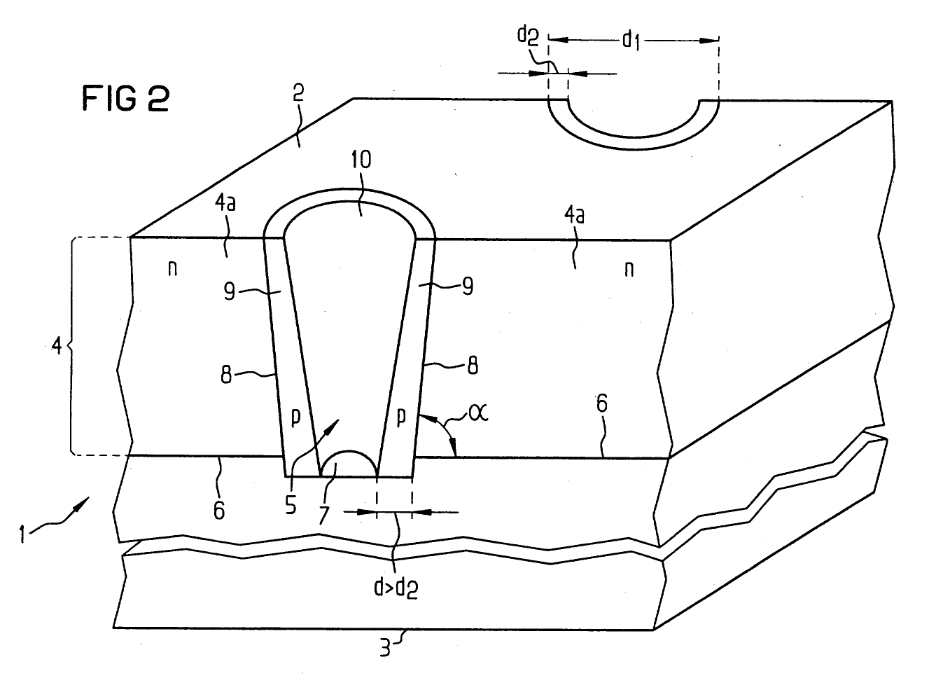

In the exemplary embodiment of FIG. 1, the trench 5 is embodied in a strip-shape form. However, the trenches 5 may have any arbitrary other form and for instance may be round (see FIG. 2), oval, rectangular, hexagonal, gridlike, etc. The trench 5 has a trench bottom 7, extending approximately parallel to the first surface 2, and trench walls 8, which are ideally disposed at a right angle to the surface 2. Typically, however, the trench walls 8 are angled from a horizontal by a berm angle α. The horizontal will hereinafter be defined through a plane of the first surface 2, and the vertical will be defined through a plane at right angles to it. A magnitude of the berm angle α, which in the present case is less than 90°, and the form of the trenches 5 are of no further significance for the present invention. The trenches 5 may have an arbitrary shape, with a berm angle larger or smaller than 90°.

In FIG. 1, a balancing layer 9 adjoining the trench walls 8 is provided inside the trench 5. The balancing layer 9, which has a conductivity type opposite that of the track region 4a, has a largely constant layer thickness d2 throughout the entire trench 5.

A preferred production method for the balancing layer 9 disposed in the semiconductor layer will now be described.

A relatively highly doped semiconductor layer of a first conductivity type is furnished, having been produced for instance by epitaxy, diffusion or ion implantation. Once the surface 2 of the semiconductor body 1 has been structured, the strip shaped trenches 5 are etched into the semiconductor layer 4. Both anisotropic etching and isotropic etching can be considered for producing the trenches 5. Via a doping deposition process, the thin balancing layer 9 of a second conductivity type is created on the trench walls 8. In the production of the thin balancing layer 9, its total charge is adjusted such that a net doping of the balancing layer 9 and the track region 4a near “zero” results, and the charge per unit of surface area does not exceed the breakdown charge in any direction in three dimensions. Moreover, the layer thickness d2 must be so thin, or the trench width d1 must be wide enough, that the balancing layer 9 in the trench 5 does not grow shut anywhere. The growing shut of the balancing layer 9 on the trench bottom 7, which necessarily occurs in the deposition process, can be removed again by an anisotropic etching process.

The dopant concentration and the layer thickness d2 of the balancing layer 9 should both be adjusted such that the total charge in the balancing layer 9 is approximately equivalent to the total charge in the track region 4a surrounding it. The layer thickness d2 and the dopant concentration of the balancing layer 9 can then be adjusted in a suitable way via the parameters of the deposition process, such as its duration, a dopant quantity supplied, a temperature, a process pressure, and so forth.

Finally, a still-empty interstice 10 between the balancing layers 9 in the trenches 5 is epitaxially filled. As a filler material for the interstice 10, undoped semiconductor material, boron phosphorus silicate glass (BPSG), or a similar undoped material can be used. Instead of filling the trenches 5 with an epitaxially deposited undoped silicon or BPSG, it is also possible for a void to remain in the interstice 10 of the trenches 5, if the walls of the balancing layer 9 toward the interstice 10 are passivated and the interstice 10 is closed off at the top by a cap, for instance of BPSG.

Instead of the above-described deposition process for producing the balancing layer 9, the layer 9 can also advantageously be produced by some other method. In this case the interstice 10 in the trench 5 is filled by epitaxial deposition of doped silicon or polysilicon or phosphorus silicate glass with a doping of the second conductivity type. The doping can then be forced in to the surrounding track region 4a of the first conductivity type via a diffusion step, thus creating a thin balancing layer 9 there. After that, the epitaxially deposited lining is etched out of the trenches 5 again. The interstice 10 is finally closed in a known manner. To obtain a clear separation between the balancing layer 9 and the track region 4a, in that case their dopant substances should each have a markedly different diffusion coefficient.

The balancing layer 9, whose doping has been adjusted such that the complete charge required for compensation is already contained in the balancing layer 9, has the effect in the case of a strip shaped configuration of the trenches 5 of a constant charge per unit of surface area over the entire depth t, as a result of which the charges in the track region 4a and in the balancing layer 9 balance one another out in the depletion mode. A constant charge per unit of surface area over the entire depth t can be attained, however, essentially only in the case of strip shaped or rectangular trenches 5. In round or oval trenches 5, on the other hand, the tapering to the depth t of the trenches 5 leads to a virtually linear decrease in the charge per unit of surface area as a function of the depth t. However, it would also be desirable for a constant charge per unit of surface area over the entire depth t to be attainable in round or oval trenches as well.

This subject matter is addressed in an exemplary embodiment shown in FIG. 2, in which the trench 5 is round. Round trenches 5 have a maximum degree of packing per unit of surface area in the layout of the cell field of a semiconductor component.

Here, the balancing layer 9 is embodied such that its thickness d2 increases with increasing depth t of the semiconductor body 1. The depth d2 of the balancing layer 9 increases with increasing depth t such that the aforementioned linear decrease in the charge per unit of surface area as a function of the depth t is compensated for. In this way, in round or oval trenches, once again a constant charge per unit of surface area over the entire depth t of the trenches 5 can be assured. Conversely, it is understood that with trenches that widen toward the depth t, the thickness d2 of the balancing layers 9 and thus the charge per unit of surface area decrease accordingly.

The optimal setting of the thickness d2 of the balancing layer 9 can be attained for instance by adding HCL during the deposition process. Adding HCL has the effect for instance that phosphorus-doped silicon is etched less markedly, because the deposition process is depth-dependent. Therefore, in regions near the surface, the balancing layer 9 is etched more markedly than in deeper regions of the trench. Another option for producing a variable thickness of the balancing layers 9 is to establish a temperature gradient along the depth t of the trenches 5.

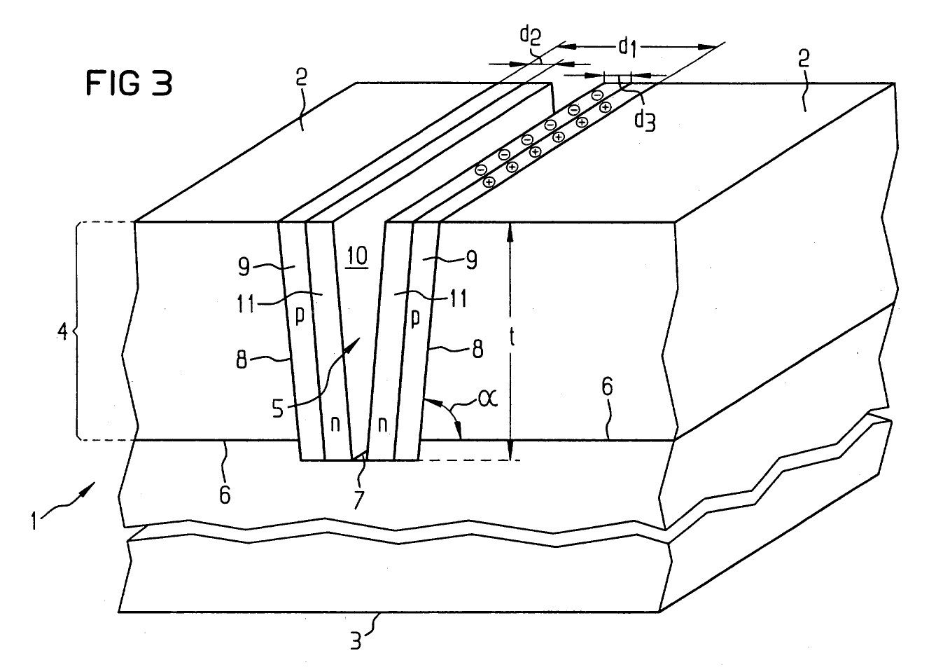

FIG. 3 shows a further exemplary embodiment in a fragmentary section through the semiconductor layer 4, in which the strip shaped trench 5 has the first balancing layer 9 and a second balancing layer 11 complementary to it.

In FIG. 3, the semiconductor layer 4 is undoped or is very weakly doped. Here the trench 5 has the first balancing layer 9 and the second balancing layer 11 complementary to it. In the present case, the first balancing layer 9 is p-doped and the second balancing layer is n-doped 11. One of the two balancing layers 9, 11 then forms the track region of the semiconductor component, while the other balancing layer 9, 11 is intended for compensation in the charges in the depletion mode of the semiconductor component.

The balancing layers 9, 11 are disposed side by side on the trench walls 8 and are joined to one another. Typically but not necessary, the two balancing layers 9, 11 have the same dopant concentrations. However, it would also be conceivable for the thickness d2 of the first balancing layer 9 and the thickness d3 of the second balancing layer 11 to differ. What is essential here is merely that the total charges of the two balancing layers 9, 11 be of approximately equal magnitude so that they compensate for one another in the depletion mode.

The balancing layers 9, 11 may be created by two successive process steps. The respective doping in one of the above production methods can be created either by a deposition process or by driving the doping in from a lining by a diffusion step. The particular advantage of such a trench 5 with two thin balancing layers 9, 11 of opposite conductivity types in an otherwise undoped semiconductor layer 4 is that if one trench 5 fails because of particles or photoresist problems during production, the semiconductor component remains fully functional.

It is known that voltage breakdowns in semiconductor components occur preferentially in the peripheral region of doping zones, because there the electrical field intensity drops with constant doping, as a consequence of the curvature of the concentration zones dictated by the periphery. To avoid such voltage breakdowns, so-called peripheral structures are used in the peripheral region of semiconductor components. The peripheral structures reduce local peaks of the field intensity in the peripheral region of the semiconductor component. For the peripheral structure, the corresponding configuration parameters are derived from the maximum allowable field and relate essentially to reliably undershooting a maximum boundary face charge in the region of the vertically extending pn junctions.

For the homogeneous creation of the peripheral region, typically the diameters d1 of the trenches 5 are decreased steadily toward the peripheral region, and as a result the total quantity of compensation charges resulting from the balancing layers 9 in the trenches 5 also decreases. In this way, a homogeneous transition from the active region of the cell field of the semiconductor component toward the peripheral region is assured.

Along with the above-described reduction in the diameter d1 of the trenches 5 in the direction of the peripheral region, it would also be conceivable to vary the shape of the trenches 5 in the direction of the peripheral region. For instance, the berm angle α could decrease to an increasing extent toward the peripheral region of the semiconductor component. Another option would for instance be to reduce the depth t toward the peripheral region. If the depth t of the trenches is varied toward the periphery, then for instance the field intensity distribution in the peripheral region can be varied in a favorable way, or the breakdown site in the depletion mode of the semiconductor component can be defined.

To compensate for charges, here the thickness d2 and the depth t of the balancing layers 9 and thus the dopant load are varied in the radial and/or vertical direction. In this way, the shape of the trenches 5 can be intentionally utilized for the sake of a lateral and vertical variation of the introduced charge dose. In this way, a gradual transition in the doping from virtually completely compensated for to markedly n or p-doped can be achieved.

The trenches according to the invention can especially advantageously be used in the semiconductor component disposed in a cell field, such as a MOSFET or an insulated gate bipolar transistor (IGBT). However, the present invention is not limited to use in such a semiconductor component, but can also be used for defined setting of the dopant concentration in the track region of arbitrary semiconductor components.

Furthermore, the invention is not exclusively limited to a complete compensation of the charges in the track region of the semiconductor component. Instead, a gradual transition in the doping in the semiconductor layer from virtually completely compensated to a pronounced n or p-doping can be created. The introduced dopings need not necessarily be of the same conductivity type, either, but instead may also have the same conductivity type but a different dopant concentration.

We claim:

1. A semiconductor body with laterally variable doping, comprising:
a semiconductor layer having a surface and at least one trench formed therein extending from said surface into said semiconductor layer to a given depth and having trench walls; and
at least one doped layer disposed in said at least one trench and connected to said trench walls for charge carrier compensation, said at least one doped layer having a layer thickness remaining substantially constant over an entire area of said given depth of said at least one trench, and twice said layer thickness of said at least one doped layer being less than a minimum spacing of said trench walls from one another.

2. The semiconductor body according to claim 1, wherein said semiconductor layer has a doping of a first conductivity type and said at least one doped layer has a doping of a second conductivity such that a total quantity of charges in said at least one doped layer and said semiconductor layer being substantially of equal magnitude so that in a depletion mode, charge carriers in said at least one doped layer and said semiconductor layer largely balance one another out.

3. The semiconductor body according to claim 1, wherein said at least one doped layer includes a first doped layer of a first conductivity type and an adjoining second doped layer of a second conductivity type and a total quantity of charges in said first doped layer and said second doped layer is substantially of equal magnitude so that in a depletion mode charge carriers in said first doped layer and said second doped layer largely balance one another out.

4. The semiconductor body according to claim 3, wherein said semiconductor layer is undoped.

5. The semiconductor body according to claim 3, wherein said semiconductor layer has a dopant concentration slighter than one of said first doped layer and said second doped layer.

6. The semiconductor body according to claim 1, wherein said at least one trench, in projection on a plane of said surface, is in one of strip-shaped and rectangular-shaped.

7. The semiconductor body according to claim 1, wherein said at least one trench, in projection on a plane of said surface, is in one of circular-shaped and oval-shaped.

8. The semiconductor body according to claim 6, wherein said layer thickness of said at least one doped layer is one of increasing and decreasing in dependence on the given depth of said at least one trench such that one of a decrease and an increase in a charge per unit of surface area is compensated for in dependence on said given depth.

9. The semiconductor body according to claim 1, including a semiconductor component having a peripheral region, a high depletion voltage strength, and a low-impedance track region, said semiconductor layer disposed in said semiconductor component.

10. The semiconductor body according to claim 9, wherein said semiconductor layer receives a charge dose and the charge dose is varied in said peripheral region of said semiconductor component in a radial direction via at least one of said layer thickness of said at least one doped layer and a diameter of said at least one doped layer and thus via a dopant level.

11. The semiconductor body according to claim 9, wherein said semiconductor layer receives a charge dose and the charged dose is varied in a vertical direction in said peripheral region of said semiconductor component via at least one of said given depth of said at least one trench and a diameter of said at least one doped layer and thus via a dopant level.

12. A method for producing a doped layer in a semiconductor material, which comprises:
furnishing a semiconductor body having a semiconductor layer;
etching trenches having trench walls into the semiconductor layer;
forming, via a doping deposition process with a predetermined dopant dose, a first doped layer of a first conductivity type on said trench walls;
performing the doping deposition process step until a predetermined layer thickness of the first doped layer being reached;
forming, via a second doping deposition process with a predetermined dopant dose, a second doped layer of a second conductivity type opposite said first conductivity type on said first doped layer for forming doped layers being adjacent doped layers; and
performing the second doping deposition process step until a predetermined layer thickness of the second doped layer being reached.

13. The method according to claim 12, which comprises filling a remaining interstice in the trenches with an undoped material via a further deposition process after the production of the doped layers.

14. The method according to claim 12, which comprises passivating the trench walls and subsequently creating a cap of undoped material over remaining interstice in the trenches after the production of the doped layers.

15. The method according to claim 13, which comprises using at least one material selected from the group consisting of polycrystalline silicon, boron phosphorus silicate glass, and quartz glass as the undoped material.

16. The method according to claim 12, which comprises performing the first doping deposition process step and the second doping deposition process step for producing the doped layers in a slightly selective etching atmosphere.

17. A method for producing a doped layer in a semiconductor material, which comprises:
furnishing a semiconductor body with a semiconductor layer; etching trenches having trench walls into the semiconductor layer;
filling the trenches by deposition of a doped, not necessarily conductive material, with a predetermined dopant dose of a first conductivity type;
forcing, via a diffusion process, dopant substances of a material into the semiconductor layer via the trench walls until a doped layer with a predetermined layer thickness being formed;
adjusting the predetermined layer thickness via at least one of the predetermined dopant dose, a duration of the diffusion process, and a temperature of the diffusion process; and
etching out again deposited material in the trenches after the diffusion process.

18. The method according to claim 17, which comprises filling a remaining interstice in the trenches with undoped material via a further deposition process after the production of the doped layer.

19. The method according to claim 17, which comprises passivating the trench walls and subsequently creating a cap of undoped material over remaining interstice in the trenches after the production of the doped layer.

20. The method according to claim 18, which comprises using at least one material selected from the group consisting of polycrystalline silicon, boron phosphorus silicate glass, and quartz glass as the undoped material.

21. The method according to claim 17, which comprises performing the deposition step for producing the doped layer in a slightly selective etching atmosphere.
